(19) United States
(12) Patent Application Publication
(10) Pub. No.: US 2018/0190795 A1
(43) Pub. Date: Jul. 5, 2018

(54) Array Substrate, Manufacturing Method Thereof, and Display Device

(71) Applicants: BOE TECHNOLOGY GROUP CO., LTD., Beijing (CN); BEIJING BOE DISPLAY TECHNOLOGY CO., LTD., Beijing (CN)

(72) Inventors: Zheng LIU, Beijing (CN); Zhichao ZHANG, Beijing (CN); Xi CHEN, Beijing (CN); Xiaoxiang ZHANG, Beijing (CN); Mingxuan LIU, Beijing (CN)

(21) Appl. No.: 15/560,374

(22) PCT Filed: Mar. 27, 2017
(86) PCT No.: PCT/CN2017/078272

§ 371 Date: Sep. 21, 2017

(30) Foreign Application Priority Data
May 5, 2016 (CN) 201610293562.9

(51) Int. Cl. H01L 29/66; H01L 29/786; H01L 27/12

(52) U.S. Cl. CPC H01L 29/66765; H01L 27/3244; H01L 27/1251; H01L 29/78678

(57) ABSTRACT

The present disclosure provides an array substrate, the array substrate being divided into a plurality of pixel units, each of which is provided with a thin film transistor therein, the thin film transistor comprising an active layer and a passivation layer, a source and a drain arranged on the active layer, wherein the passivation layer is formed with a source via hole penetrating the passivation layer, a drain via hole penetrating the passivation layer, and a data line slot communicated with the source via hole; the source is arranged in the source via hole to be connected with the active layer; the drain is arranged in the drain via hole to be connected with the active layer; a data line is arranged in the data line slot to be electrically connected with corresponding source. The present disclosure also provides a manufacturing method of an array substrate and a display device.

### TECHNICAL FIELD

Embodiments of the present invention relate to the field of display technology, and in particular relate to an array substrate, a manufacturing method of the array substrate, and a display device including the array substrate.

### BACKGROUND

Thin film transistors are important switch elements applied to array substrates, and can be divided into oxide thin film transistors and polysilicon thin film transistors according to different materials of active layers.

During manufacture of a polysilicon thin film transistor, a metal layer can be directly formed over the active layer after an active layer has been formed, and then a wet-etching patterning process is carried out on the metal layer to obtain a source and a drain.

During manufacture of an oxide thin film transistor, an etch stop layer needs to be formed over the active layer after an active layer has been formed, and then a source and a drain are formed by etching.

As electronic products become diversified, there is a requirement for diverse structures of array substrates. Accordingly, how to provide a thin film transistor having a novel structure and convenient to manufacture has become a technical problem to be solved urgently in the art.

### SUMMARY

An object of embodiments of the present invention is at least providing an array substrate, a manufacturing method of the array substrate, and a display device. The array substrate has a novel structure, and meets the requirement of diverse structures of array substrates in the market.

To achieve the above object, in an aspect of embodiments of the present invention, an array substrate is provided, the array substrate being divided into a plurality of pixel units, each of which is provided with a thin film transistor therein, the thin film transistor including an active layer, and a passivation layer, a source and a drain arranged on the active layer, wherein the passivation layer is formed with a source via hole penetrating through the passivation layer, a drain via hole penetrating through the passivation layer, and a data line slot communicated with the source via hole; the source is arranged in the source via hole to be connected with the active layer; the drain is arranged in the drain via hole to be connected with the active layer; and a data line is arranged in the data line slot to be electrically connected with the source arranged in the source via hole communicated with the data line slot.

Upper surfaces of the source, the drain and the data line slot may be flush with an upper surface of the passivation layer.

The source may include a source anti-diffusion metal layer and a source core material, the source anti-diffusion metal layer being located between an outer surface of the source via hole and the source core material;

the drain includes a drain anti-diffusion metal layer and a drain core material, the drain anti-diffusion metal layer being located between an outer surface of the drain via hole and the drain core material; and

the data line includes a data line anti-diffusion metal layer and a data line core material, the data line anti-diffusion metal layer being located between an outer surface of the data line slot and the data line core material.

The source core material, the drain core material and the data line core material may be all made of copper; and the source anti-diffusion metal layer, the drain anti-diffusion metal layer and the data line anti-diffusion metal layer may be all made of molybdenum or molybdenum alloy.

The array substrate may further include a pixel electrode arranged in each of the pixel units, the pixel electrode being formed on the passivation layer and electrically connected with the drain.

The array substrate may further include a plurality of source protectors and a plurality of data line upper protectors, wherein each source corresponds to one source protector, and each data line corresponds to one data line upper protector; the source protector and the data line upper protector are arranged in a same layer as the pixel electrode; and the source protector and the data line upper protector are made of a same material as the pixel electrode.

The active layer may be made of an oxide.

The array substrate may further include a gate, a gate line and a gate insulating layer, the gate insulating layer being arranged between a layer where the gate is located and the active layer, and located below the active layer; and the array substrate further includes a plurality of data line lower protectors, which are arranged in a same layer as the active layer, each data line corresponding to one data line lower protector, and the data line lower protector being located under the corresponding data line.

In another aspect of embodiments of the present invention, a manufacturing method of an array substrate is provided, the manufacturing method including:

forming, on a base substrate, a pattern including an active layer, the base substrate being divided into a plurality of areas for forming a plurality of pixel units, the active layer being formed in each pixel unit;

forming a passivation layer over the pattern including the active layer;

forming an source via hole, a drain via hole and a data line slot in the passivation layer, the source via hole and the drain via hole both penetrating through the passivation layer, the source via hole and the drain via hole being located above the active layer to expose part of an upper surface of the active layer, and the data line slot being communicated with the corresponding source via hole; and

forming a pattern of a source, a drain and a data line, the source being located in the source via hole, the drain being located in the drain via hole, and the data line being located in the data line slot and electrically communicated with the corresponding source.

The step of forming a pattern of a source, a drain and a data line may include:

forming a metal layer such that a part of the metal layer is located in the source via hole, the drain via hole and the data line slot; and

grinding the metal layer to remove a part of the metal layer located on an upper surface of the passivation layer while only retaining the part of the metal layer located in the source via hole, the drain via hole and the data line slot, such that the part of the metal layer located in the source via hole forms the source, the part of the metal layer located in the drain via hole forms the drain, and the part of the metal layer located in the data line slot forms the data line.

Optionally, the source includes a source anti-diffusion metal layer and a source core material, the source anti-diffusion metal layer being located between an outer surface of the source via hole and the source core material;

the drain includes a drain anti-diffusion metal layer and a drain core material, the drain anti-diffusion metal layer being located between an outer surface of the drain via hole and the drain core material; and

the data line includes a data line anti-diffusion metal layer and a data line core material, the data line anti-diffusion metal layer being located between an outer surface of the data line slot and the data line core material;

the step of forming a metal layer includes:

forming an anti-diffusion metal layer; and

forming a core material metal layer, wherein

after the step of grinding the metal layer, a part of the anti-diffusion metal layer located in the source via hole forms the source anti-diffusion metal layer, and a part of the core material metal layer located in the source via hole forms the source core material; a part of the anti-diffusion metal layer located in the drain via hole forms the drain anti-diffusion metal layer, and a part of the core material metal layer located in the drain via hole forms the drain core material; and a part of the anti-diffusion metal layer located in the data line slot forms the data line anti-diffusion metal layer, and a part of the core material metal layer located in the data line slot forms the data line core material.

The anti-diffusion metal layer may be made of molybdenum or molybdenum alloy, and the core material metal layer may be made of copper.

The metal layer may be grinded by a chemical-mechanical grinding process in the step of grinding the metal layer.

The metal layer may be grinded by using a grinding fluid, which may include a mixture of grinding particles and water.

The manufacturing method may further include, after the step of forming a pattern of a source, a drain and a data line:

forming a pattern of pixel electrodes, source protectors and data line upper protectors, each pixel electrode being provided therein with one pixel electrode, which is electrically connected with the drain, each source corresponding to one source protector, each data line corresponding to one data line upper protector, the source protector covering the source, and the data line upper protector covering the data line.

The active layer may be made of a metal oxide.

The manufacturing method may further include, before the step of forming, on a base substrate, a pattern including an active layer:

providing the base substrate, including:
providing a glass substrate;
forming, on the glass substrate, a pattern including a gate and a gate line; and
forming a gate insulating layer;

wherein the pattern including the active layer further includes a plurality of data line lower protectors, each data line corresponding to one data line lower protector, and the data line lower protector being located under the corresponding data line.

The grinding particles may include silicon dioxide particles.

In a further aspect of embodiments of the present invention, there is provided a display device including an array substrate, wherein the array substrate is one of the array substrates provided by embodiments of the present invention.

Embodiments of the present invention provide the array substrate with a novel structure, and the active layer of the array substrate is not limited by manufacturing process.

### BRIEF DESCRIPTION OF THE FIGURES

The accompanying drawings are intended to provide further understanding of embodiments of the present invention and form part of the specification, and are used for illustrating rather than limiting the present invention, together with following specific implementations. In the drawings:

FIG. 1 is a sectional structure diagram of a part of an array substrate provided by an embodiment of the present invention including a thin film transistor, taken along line A-A in FIG. 2;

FIG. 2 is a top structure diagram of a part of an array substrate provided by an embodiment of the present invention;

FIG. 3 is a diagram illustrating a base substrate after a common electrode has been formed in manufacturing an array substrate;

FIG. 4 is a diagram illustrating a base substrate after a pattern including a gate has been formed in manufacturing an array substrate;

FIG. 5 is a diagram illustrating a base substrate after a pattern including an active layer has been formed in manufacturing an array substrate;

FIG. 6 is a top view of part of an active layer pattern;

FIG. 7 is a schematic diagram illustrating formation of a source via hole and a drain via hole in a passivation layer in manufacturing the array substrate;

FIG. 8 is a diagram illustrating a base substrate after a metal layer has been formed in manufacturing an array substrate; and

FIG. 9 is a diagram illustrating a base substrate that has been subjected to a grinding step in manufacturing an array substrate.

### DETAILED DESCRIPTION

Specific embodiments of the present invention are described in detail below in conjunction with the accompanying drawings. It should be understood that the specific embodiments described herein are only used for illustrating and explaining the present invention, instead of limiting the present invention.

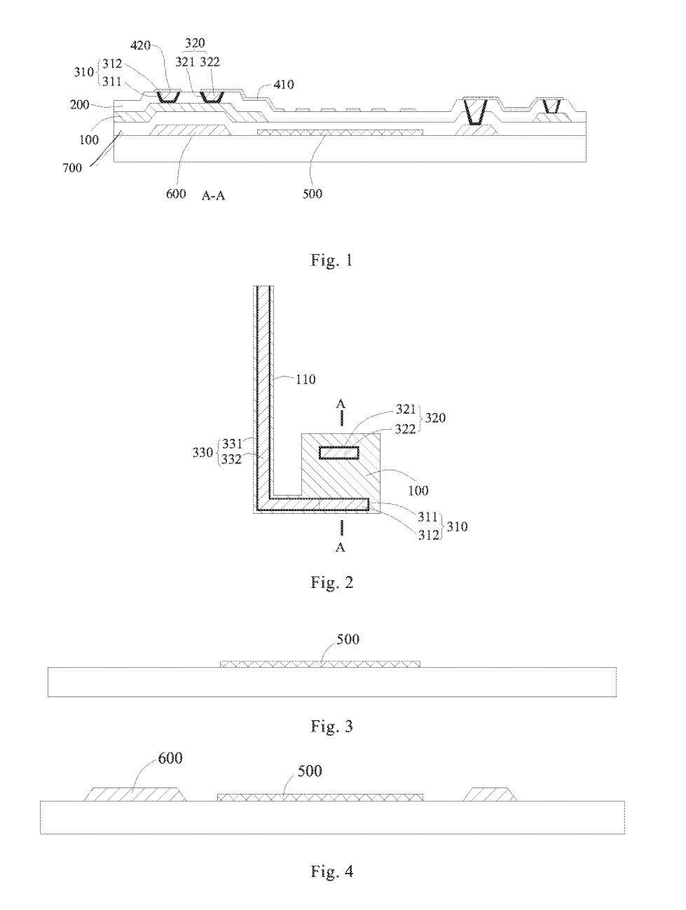

In an aspect of embodiments of the present invention, an array substrate is provided, the array substrate being divided into a plurality of pixel units, each of which is provided with a thin film transistor therein, the thin film transistor including an active layer 100 and a passivation layer 200, a source 310 and a drain 320 arranged on the active layer 100, wherein the passivation layer 200 is formed with a source via hole penetrating through the passivation layer 200, a drain via hole penetrating through the passivation layer 200, and a data line slot communicated with the source via hole. The source 310 is arranged in the source via hole to be connected with the active layer 100, and the drain 320 is arranged in the drain via hole to be connected with the active layer 100. As shown in FIG. 2, a data line 330 is arranged in the data line slot to be electrically connected with the corresponding source 310.

It is readily understandable to those skilled in the art that the part of the thin film transistor in FIG. 1 is shown in a sectional view taken along line A-A of FIG. 2. Furthermore, the corresponding relation between the data line and the source is also well known to those skilled in the art. As an implementation of embodiments of the present invention, sources of thin film transistors in a same column of pixel units may correspond to a same data line. Of course, embodiment of the present invention are not limited thereto. The data line and the source may also have other corresponding relations, which will not be listed herein.

In manufacturing the array substrate provided by embodiments of the present invention, a metal layer is directly disposed on the passivation layer 200 after the source via hole, the drain via hole and the data line slot have been formed, and the material of the metal layer can be filled into the source via hole, the drain via hole and the data line slot. Next, redundant metal above the passivation layer is removed by a grinding process while only metal filled into the source via hole, the drain via hole and the data line slot is retained, wherein the metal layer material remaining in the source via hole forms the source, the metal layer material remaining in the drain via hole forms the drain, and the metal layer material remaining in the data line slot forms the data line. As such, no mask is needed when a patterning process is performed on the metal layer to form the source, the drain and the data line, and thus the cost can be saved.

Moreover, in the array substrate provided by embodiments of the present invention, the specific material for forming the active layer 100 is not particularly limited. The active layer 100 may be prepared from a polysilicon material, and may also be prepared from an oxide (such as IGZO).

Embodiments of the present invention provide an array substrate with a novel structure, and the active layer of the array substrate is not limited by manufacturing process.

To facilitate forming the source, the drain and the data line by the grinding process to obtain the array substrate, in an implementation of embodiments of the present invention, as shown in FIG. 1, the upper surfaces of the source 310, the drain 320 and the data line are flush with the upper surface of the passivation layer 200. Here, the orientation “upper” refers to an up direction in FIG. 1.

It is readily understandable to those skilled in the art that in the array substrate, the source, the drain and the data line are all made of a metal material. The source, the drain and the data line may be made of one material. The source, the drain and the data line may also be made of a metal layer structure formed by layers of different metal materials and having a “stacked structure”. A layer of metal in direct contact with the passivation layer 200 may be used for preventing diffusion of other layers of metal.

Specifically, as shown in FIGS. 1 and 2, the source 310 includes a source anti-diffusion metal layer 311 and a source core material 312, the source anti-diffusion metal layer 311 being located between the source core material 312 and an outer surface of the source via hole. Specifically, the outer surface of the source via hole includes a side wall and a bottom wall of the source via hole. That is, the source anti-diffusion metal layer 311 is in direct contact with the outer surface of the source via hole, to prevent diffusion of the metal forming the source core material 312.

The drain 320 includes a drain anti-diffusion metal layer 321 and a drain core material 322, the drain anti-diffusion metal layer 321 being located between an outer surface of the drain via hole and the drain core material 322. Specifically, the outer surface of the drain via hole includes a side wall and a bottom wall of the drain via hole. That is, the drain anti-diffusion metal layer 321 is in direct contact with the outer surface of the drain via hole, to prevent diffusion of the metal forming the drain core material 322.

As shown in FIG. 2, the data line 330 includes a data line anti-diffusion metal layer 331 and a data line core material 332, the data line anti-diffusion metal layer 331 being located between an outer surface of the data line slot and the data line core material 332. Specifically, the outer surface of the data line slot includes a side wall and a bottom wall of the data line slot. That is, the data line anti-diffusion metal layer 331 is in direct contact with the outer surface of the data line slot, to prevent diffusion of the metal forming the data line core material 332.

Generally, other functional layers such as a passivation protection layer and an orientation layer can also be formed over the data line, the source and the like. With arrangement of the data line slot of embodiments of the present invention, an overall thickness of a structure such as the data line and the source can be reduced, facilitating formation of other functional layers thereon.

Generally, a metal with high electrical conductivity is used for preparing the source core material 312, the drain core material 322 and the data line core material 332. Optionally, the source core material 312, the drain core material 322 and the data line core material 332 are all made of copper. Correspondingly, a metal with poor diffusion is used for preparing the source anti-diffusion metal layer 311, the drain anti-diffusion metal layer 321 and the data line anti-diffusion metal layer 331. Optionally, the source anti-diffusion metal layer 311, the drain anti-diffusion metal layer 321 and the data line anti-diffusion metal layer 331 are all made of molybdenum or molybdenum alloy.

It is readily understandable to those skilled in the art that the array substrate further includes a pixel electrode 410 arranged in each of the pixel units, the pixel electrode 410 being formed on the passivation layer 200 and electrically connected with the drain 320.

As described above, the source core material 312, the drain core material 322 and the data line core material 332 are all made of a material with high electrical conductivity. To prevent oxidation of the source core material 312 and the data line core material 322 during manufacture, optionally, as shown in FIG. 1, the array substrate further includes a plurality of source protectors 420 and a plurality of data line upper protectors, wherein each source 310 corresponds to one source protector 420, and each data line 330 corresponds to one data line upper protector; and the source protector 420 and the data line upper protector are arranged in a same layer and made of a same material as the pixel electrode 410.

The source protector 420 and the data line upper protector are made of ITO (Indium Tin Oxide) and have strong anti-oxidation property, and thus the source core material 312 and the data line core material 332 can be well protected. As the drain core material 322 is covered with the pixel electrode 410 thereon, there is no need to provide other protection layer on the drain core material 322. The pixel electrode 410 is also made of ITO.

Although the material for forming the active layer 100 is not particularly limited in embodiments of the present invention, optionally the active layer 100 is made of an oxide. Specifically, the active layer 100 may be made of IGZO.

In the present application, the specific structure of the thin film transistor is not particularly limited. For example, the thin film transistor may be of a bottom-gate structure, as shown in the figures, the array substrate including a gate 600, a gate line and a gate insulating layer 700, the gate insulating layer being arranged between a layer where the gate is located and the active layer, and located below the active layer 100. As shown in FIG. 2, the array substrate further includes a plurality of data line lower protectors 110, which are arranged in a same layer as the active layer 100, each data line 330 corresponding to one data line lower protector 110, and the data line lower protector 110 being located under the corresponding data line 330. The purpose of providing the data line lower protection layer is preventing the gate insulating layer below the data line slot from being penetrated during formation of the data line slot by etching, so that short-circuit between the gate line and the data line can be avoided.

In another aspect of embodiments of the present invention, a manufacturing method of an array substrate is provided, the manufacturing method including:

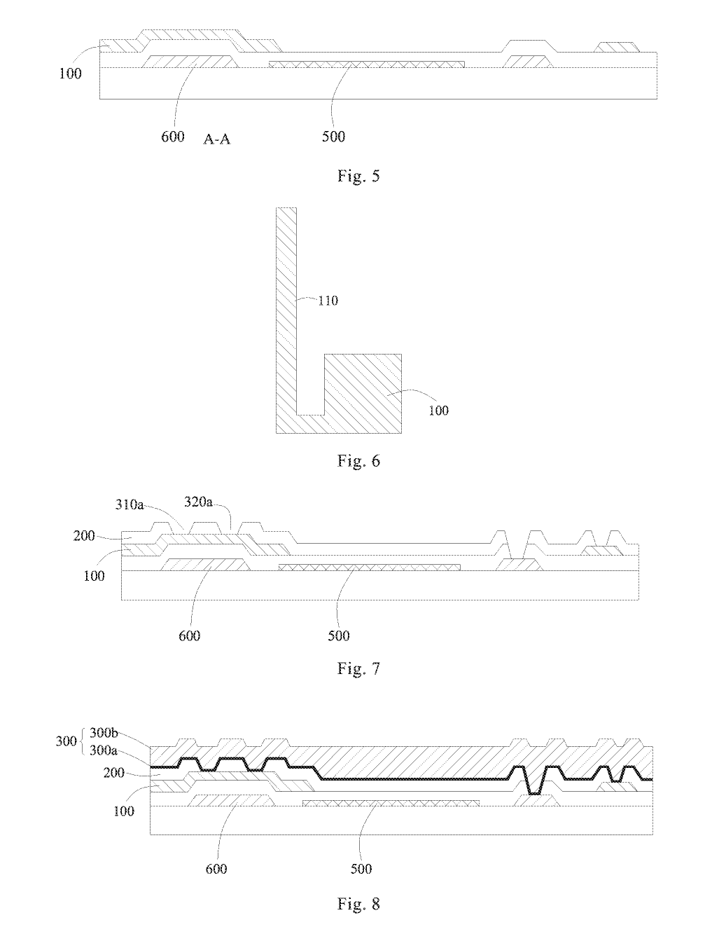

forming, on a base substrate, a pattern including an active layer 100, as shown in FIG. 5; the base substrate being divided into a plurality of areas for forming a plurality of pixel units, the active layer 100 being formed in each pixel unit;

forming a passivation layer 200 over the pattern including the active layer 100, as shown in FIG. 7;

forming an source via hole 310a, a drain via hole 320a and a data line slot in the passivation layer 200, the source via hole 310a and the drain via hole 320a both penetrating through the passivation layer 200, the source via hole 310a and the drain via hole 320a being located above the active layer 100 to expose a part of the upper surface of the active layer 100, as shown in FIG. 7; wherein the data line slot is communicated with the corresponding source via hole 310a; and

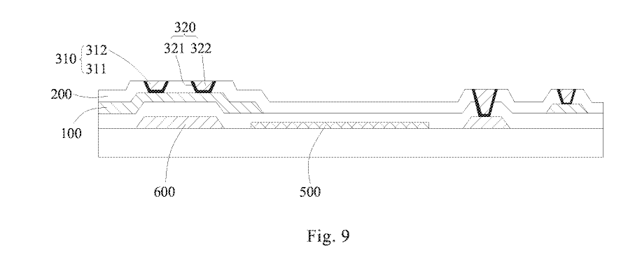

forming a pattern of a source 310, a drain 320 and a data line, wherein the source 310 is located in the source via hole, and the drain 320 is located in the drain via hole, as shown in FIG. 9; and the data line is located in the data line slot and electrically communicated with the corresponding source.

The above-mentioned array substrate provided by embodiments of the present invention can be obtained by using the manufacturing method provided by embodiments of the present invention.

To reduce the number of masks used in the manufacturing method and reduce the cost, optionally, the step of forming a pattern of a source 310, a drain 320 and a data line includes:

forming a metal layer 300, part of the material of the metal layer 300 being filled into the source via hole and the drain via hole, as shown in FIG. 8; and part of the material of the metal layer 300 being filled into the data line slot; and

grinding the metal layer 300 to remove the part of the metal layer 300 located on the upper surface of the passivation layer 200 while only retaining the part of the metal layer 300 filled into the source via hole, the drain via hole and the data line slot, such that the part of the metal layer 300 filled into the source via hole forms the source 310, the part of the metal layer 300 filled into the drain via hole forms the drain 320, and the part of the metal layer 300 filled into the data line slot forms the data line.

The source, the drain and the data line can be obtained by grinding the metal layer 300, so that the masks used in the manufacturing method can be reduced, and the cost of the manufacturing method can be lowered.

As described above, in another implementation of the present invention, the source 310 includes a source anti-diffusion metal layer 311 and a source core material 312, the source anti-diffusion metal layer 311 being located between the source core material 312 and an outer surface of the source via hole.

The drain 320 includes a drain anti-diffusion metal layer 321 and a drain core material 322, the drain anti-diffusion metal layer 321 being located between an outer surface of the drain via hole and the drain core material 322.

The data line 330 includes a data line anti-diffusion metal layer 331 and a data line core material 332, the data line anti-diffusion metal layer 331 being located between an outer surface of the data line slot and the data line core material 332.

Correspondingly, the step of forming a metal layer 300 includes:

forming an anti-diffusion metal layer 300a; and

forming a core material metal layer 300b.

In the step of grinding the metal layer, as shown in FIG. 9, the part of the anti-diffusion metal layer located in the source via hole forms the source anti-diffusion metal layer 311, and the part of the core material metal layer located in the source via hole forms the source core material 312. The part of the anti-diffusion metal layer located in the drain via hole forms the drain anti-diffusion metal layer 321, and the part of the core material metal layer located in the drain via hole forms the drain core material 322. The part of the anti-diffusion metal layer located in the data line slot forms the data line anti-diffusion metal layer 331, and the part of the core material metal layer located in the data line slot forms the data line core material 332.

Optionally, the anti-diffusion metal layer is made of molybdenum or molybdenum alloy, and the core material metal layer is made of copper.

In order to improve mask efficiency, preferably, the metal layer is grinded by a chemical-mechanical grinding process in the step of grinding the metal layer.

Chemical-mechanical grinding includes chemical grinding and mechanical grinding. For example, when the metal of the source and the drain is Cu, the grinding liquid may generally include H₂O₂, a grinding fluid and additives. As the contact area between the metal material and the grinding liquid is different at locations such as the data line slot and recesses of the source and the drain and at locations with large metal areas, the grinding speed is not consistent. That is to say, at recessed locations, the contact area between the metal material, which has a low density, and the grinding liquid is small, resulting in a lowered metal grinding speed at the locations; and at non-recessed locations, large areas of metal are exposed to the grinding liquid, and under the effect of mechanical grinding, the grinding speed is much higher than that at recessed locations, which can thus ensure the recessed locations are not grinded. Moreover, as PVX (SiNx) and metal are in a selection ratio, it can ensure the PVX is not grinded, thus forming the structure shown in the figures.

Optionally, the grinding fluid used in the step of grinding the metal layer includes a mixture of grinding particles and water, wherein the grinding particles may include silicon dioxide particles. In addition, the grinding fluid may also include additives for adjusting the fluidity of the grinding fluid, etc.

Optionally, the method includes, after chemical grinding:

a step of forming a pattern of pixel electrodes, source protectors and data line upper protectors, each pixel electrode being provided therein with one pixel electrode, which is electrically connected with the drain, each source corresponding to one source protector, each data line corresponding to one data line upper protector, the source protector covering the source, and the data line upper protector covering the data line.

Optionally, the active layer is made of a metal oxide.

It is readily understandable that the manufacturing method includes, before the step of forming, on a base substrate, a pattern including an active layer:

a step of providing the base substrate, including:
providing a glass substrate;
forming, on the glass substrate, a pattern including a gate 600 and a gate line; and
forming a gate insulating layer.

Correspondingly, as shown in FIG. 6, a pattern including the active layer further includes a plurality of data line lower protectors 110, each data line corresponding to one data line lower protector 110, and the data line lower protector 110 being located under the corresponding data line.

In embodiments of the present invention, the base substrate may include the glass substrate, a common electrode 500 formed on the glass substrate, a pattern including the gate 600 formed on the glass substrate, and a gate insulating layer covering the pattern including the gate 600.

Accordingly, in an implementation of embodiments of the present invention, the step of providing the base substrate may include:

forming, on the glass substrate, a pattern including the common electrode 500, as shown in FIG. 3;

forming, on the glass substrate, a pattern including the gate 600, as shown in FIG. 4; and

forming the gate insulating layer above the pattern including the gate 600 and the pattern including the common electrode 600.

In another aspect of embodiments of the present invention, a display device is provided, the display device including an array substrate, wherein the array substrate is one of the array substrates provided by embodiments of the present invention.

The display device may be any product or component having a display function, such as a liquid crystal display panel, an electronic paper, an OLED panel, a mobile phone, a tablet computer, a television, a display, a notebook computer, a digital photo frame, a navigator, or the like.

In manufacturing the array substrate provided by embodiments of the present invention, the metal layer is directly disposed on the passivation layer after the source via hole, the drain via hole and the data line slot are formed, and part of the metal layer can be located in the source via hole, the drain via hole and the data line slot. After that, the redundant part of the metal layer above the passivation layer is removed by the grinding process while only the part of the metal located in the source via hole, the drain via hole and the data line slot is retained, such that the metal layer material remaining in the source via hole forms the source, the metal layer material remaining in the drain via hole forms the drain, and the metal layer material remaining in the data line slot forms the data line. As such, no mask is needed when a patterning process is performed on the metal layer to form the source, the drain and the data line, and thus the cost can be saved and the process efficiency can be improved.

Moreover, in the array substrate provided by embodiments of the present invention, the specific material for forming the active layer is not particularly limited. The active layer may be prepared from a polysilicon material, and may also be prepared from an oxide (such as IGZO).

It can be understood that the foregoing implementations are only exemplary embodiments for illustrating the principle of the present invention; however, the present invention is not limited thereto. For those of ordinary skill in the art, various modifications and improvements can be made without departing from the spirit and essence of the present invention, and these modifications and improvements are also encompassed within the protection scope of the present invention.

1. An array substrate, the array substrate being divided into a plurality of pixel units, each of which is provided with a thin film transistor therein, the thin film transistor comprising an active layer and a passivation layer, a source and a drain arranged on the active layer, wherein the passivation layer is formed with a source via hole penetrating through the passivation layer, a drain via hole penetrating through the passivation layer, and a data line slot communicated with the source via hole; the source is arranged in the source via hole to be connected with the active layer; the drain is arranged in the drain via hole to be connected with the active layer; and a data line is arranged in the data line slot to be electrically connected with the source arranged in the source via hole communicated with the data line slot.

2. The array substrate of claim 1, wherein upper surfaces of the source, the drain and the data line slot are flush with an upper surface of the passivation layer.

3. The array substrate of claim 1, wherein the source comprises a source anti-diffusion metal layer and a source core material, the source anti-diffusion metal layer being located between an outer surface of the source via hole and the source core material;
the drain comprises a drain anti-diffusion metal layer and a drain core material, the drain anti-diffusion metal layer being located between an outer surface of the drain via hole and the drain core material; and
the data line comprises a data line anti-diffusion metal layer and a data line core material, the data line anti-diffusion metal layer being located between an outer surface of the data line slot and the data line core material.

4. The array substrate of claim 3, wherein the source core material, the drain core material and the data line core material are all made of copper; and the source anti-diffusion metal layer, the drain anti-diffusion metal layer and the data line anti-diffusion metal layer are all made of molybdenum or molybdenum alloy.

5. The array substrate of claim 1, further comprising a pixel electrode arranged in each of the pixel units, the pixel electrode being formed on the passivation layer and electrically connected with the drain.

6. The array substrate of claim 5, further comprising a plurality of source protectors, wherein each source corresponds to one source protector; and the source protector and the pixel electrode are arranged in a same layer and made of a same material.

7. The array substrate of claim 1, wherein the source is made of an oxide.

8. The array substrate of claim 1, further comprising a gate and a gate insulating layer, the gate insulating layer being arranged between a layer where the gate is located and the active layer, and located below the active layer; and the array substrate further comprising a plurality of data line lower protectors, which are arranged in a same layer as the active layer, each data line corresponding to one data line lower protector, and the data line lower protector being located under the corresponding data line.

9. A manufacturing method of an array substrate, comprising:
forming, on a base substrate, a pattern comprising an active layer, the base substrate being divided into a plurality of areas for forming a plurality of pixel units, the active layer being formed in each pixel unit;
forming a passivation layer over the pattern comprising the active layer;
forming an source via hole, a drain via hole and a data line slot in the passivation layer, the source via hole and the drain via hole both penetrating through the passivation layer, the source via hole and the drain via hole being located above the active layer to expose a part of an upper surface of the active layer, and the data line slot being communicated with the corresponding source via hole; and
forming a pattern of a source, a drain and a data line, the source being located in the source via hole, the drain being located in the drain via hole, and the data line being located in the data line slot and electrically communicated with the corresponding source.

10. The manufacturing method of claim 9, wherein the step of forming a pattern of a source, a drain and a data line comprises:
forming a metal layer such that a part of the metal layer is located in the source via hole, the drain via hole and the data line slot; and
grinding the metal layer to remove a part of the metal layer located on an upper surface of the passivation layer while retaining the part of the metal layer located in the source via hole, the drain via hole and the data line slot, such that the part of the metal layer located in the source via hole forms the source, the part of the metal layer located in the drain via hole forms the drain, and the part of the metal layer located in the data line slot forms the data line.

11. The manufacturing method of claim 10, wherein the source comprises a source anti-diffusion metal layer and a source core material, the source anti-diffusion metal layer being located between an outer surface of the source via hole and the source core material;
the drain comprises a drain anti-diffusion metal layer and a drain core material, the drain anti-diffusion metal layer being located between an outer surface of the drain via hole and the drain core material; and
the data line comprises a data line anti-diffusion metal layer and a data line core material, the data line anti-diffusion metal layer being located between an outer surface of the data line slot and the data line core material;
the step of forming a metal layer comprises:
forming an anti-diffusion metal layer; and
forming a core material metal layer, wherein
after the step of grinding the metal layer, a part of the anti-diffusion metal layer located in the source via hole forms the source anti-diffusion metal layer, and a part of the core material metal layer located in the source via hole forms the source core material; a part of the anti-diffusion metal layer located in the drain via hole forms the drain anti-diffusion metal layer, and a part of the core material metal layer located in the drain via hole forms the drain core material; and a part of the anti-diffusion metal layer located in the data line slot forms the data line anti-diffusion metal layer, and a part of the core material metal layer located in the data line slot forms the data line core material.

12. The manufacturing method of claim 11, wherein the anti-diffusion metal layer is made of molybdenum or molybdenum alloy, and the core material metal layer is made of copper.

13. The manufacturing method of claim 10, wherein the metal layer is grinded by a chemical-mechanical grinding process in the step of grinding the metal layer.

14. The manufacturing method of claim 10, wherein the metal layer is grinded by using a grinding fluid, which comprises a mixture of grinding particles and water.

15. The manufacturing method of claim 9, further comprising, after the step of forming a pattern of a source, a drain and a data line:
a step of forming a pattern of pixel electrodes and source protectors, each pixel electrode being provided therein with one pixel electrode, which is electrically connected with the drain, each source corresponding to one source protector, the source protector covering the source.

16. The array substrate of claim 9, wherein the source is made of a metal oxide.

17. The manufacturing method of claim 9, further comprising, before the step of forming, on a base substrate, a pattern comprising an active layer:
providing the base substrate, comprising:
providing a glass substrate;
forming, on the glass substrate, a pattern comprising a gate; and
forming a gate insulating layer;
wherein the pattern comprising the active layer further comprises a plurality of data line lower protectors, each data line corresponding to one data line lower protector, and the data line lower protector being located under the corresponding data line.

18. The manufacturing method of claim 14, wherein the grinding particles comprise silicon dioxide particles.

19. A display device, comprising an array substrate, wherein the array substrate is the array substrate of claim 1.
